(19) United States
(12) Patent Application Publication
(10) Pub. No.: US 2025/0284320 A1
(43) Pub. Date: Sep. 11, 2025

(54) CAMERA STRUCTURE AND ELECTRONIC DEVICE INCLUDING SAME

(71) Applicant: SAMSUNG ELECTRONICS CO., LTD., Suwon-si (KR)

(72) Inventor: Hyundo Song, Suwon-si (KR)

(73) Assignee: SAMSUNG ELECTRONICS CO., LTD., Suwon-si (KR)

(21) Appl. No.: 19/215,799

(22) Filed: May 22, 2025

Related U.S. Application Data
(63) Continuation of application No. PCT/KR2023/019028, filed on Nov. 23, 2023.

(30) Foreign Application Priority Data
Nov. 23, 2022 (KR) 10-2022-0158672
Dec. 6, 2022 (KR) 10-2022-0169006

(51) Int. Cl. G06F 1/16; H04N 23/51; H04N 23/55; H04N 23/57; H05K 1/02; H05K 9/00

(52) U.S. Cl. CPC G06F 1/1658; H04N 23/51; H04N 23/55; H04N 23/57; H05K 1/0215; H05K 9/0067

(57) ABSTRACT

An electronic device includes a printed circuit board with at least one ground portion, a camera electrically connected to the printed circuit board, and a camera bracket positioned in a first direction with respect to the camera. The camera bracket has a first opening corresponding to a lens of the camera. A conductive adhesive member with conductive material is positioned on the camera bracket and connected to the ground portion. A metal camera housing forms a first exterior portion of the device with a second opening corresponding to the first opening, positioned in the first direction with respect to the camera bracket and contacting the conductive adhesive member. A cover member forms a second exterior portion of the device with a third opening positioned in the first direction with respect to the camera housing, where at least a portion of the camera housing is exposed through the third opening.

### CROSS-REFERENCE TO RELATED APPLICATION

This application is a by-pass continuation application of International Application No. PCT/KR2023/019028, filed on Nov. 23, 2023, which is based on and claims priority to Korean Patent Application No. 10-2022-0158672, filed on Nov. 23, 2022, and Korean Patent Application No. 10-2022-0169006, filed on Dec. 6, 2022 in the Korean Patent Office, the disclosures of which are incorporated by reference herein in their entireties.

### 1. FIELD

The present disclosure relates to a camera structure and an electronic device that provides electrostatic discharge (ESD) protection by electrically connecting a metal camera housing to a ground portion of a printed circuit board via a conductive adhesive member.

### 2. DESCRIPTION OF RELATED ART

An ESD phenomenon may occur between an electronic component and electrical objects made of a conductive material. The ESD phenomenon may refer to an electrical phenomenon generated by instantaneous movement of electric charges accumulated in one portion by various factors to another portion. An ESD phenomenon may occur in electronic components due to electric charges accumulated inside or outside an electronic device. Since ESD is accompanied by a strong voltage, when the ESD phenomenon occurs in an electronic component, the electronic component may be damaged. Such damage may cause problems in which the electronic device may not function properly or the performance of the electronic device may be deteriorated. In order to resolve the ESD phenomenon, it is becoming important to design a path for allowing ESD to flow to a ground included in an electronic device.

### SUMMARY

According to an aspect of the disclosure, an electronic device includes a printed circuit board comprising at least one ground portion; a camera connected to the printed circuit board; a camera bracket positioned in a first direction with respect to the camera, wherein the camera bracket comprises a first opening corresponding to a lens of the camera; a conductive adhesive member positioned on the camera bracket and connected to the at least one ground portion of the printed circuit board, the conductive adhesive member comprising a conductive material; a camera housing forming an exterior portion of the electronic device, wherein the camera housing comprises a metal material and a second opening corresponding to the first opening, and the camera housing is positioned in the first direction with respect to the camera bracket and contacts the conductive adhesive member; and a cover member forming an exterior portion of the electronic device and comprising a third opening positioned in the first direction with respect to the camera housing, wherein at least a portion of the camera housing is exposed through the third opening.

The camera bracket may include at least one first hole, wherein the camera housing may include a first extension positioned in the at least one first hole of the camera bracket, and wherein the conductive adhesive member may include a second extension positioned in the at least one first hole of the camera bracket and contact the first extension of the camera housing.

The camera bracket may include a body and a seating portion protruding from the body, and wherein the conductive adhesive member may include a first conductive adhesive member, positioned on the body, bonding the camera bracket to a cover member, the first conductive adhesive member comprising the second extension that is positioned in the at least one first hole, and a second conductive adhesive member, positioned on the seating portion, bonding the camera bracket to the camera housing.

The camera bracket may include a protrusion protruding from a surface surrounding the at least one first hole and pressing against the first extension of the camera housing and the second extension of the conductive adhesive member.

The camera bracket may include a second hole positioned adjacent to the at least one first hole; and a partition wall partitioning the at least one first hole and the second hole, wherein the protrusion is positioned on the partition wall.

At least a portion of the second extension of the conductive adhesive member may be separated from the camera bracket in the first direction.

The first extension of the camera housing may be positioned at an angle with respect to the first direction.

The camera housing may include a first groove positioned on a first side with respect to the first extension and a second groove positioned on a second side with respect to the first extension.

The camera bracket may include a body and a seating portion protruding from the body, and wherein the conductive adhesive member may include a first conductive adhesive member, positioned on the body, bonding the camera bracket and a cover member; a second conductive adhesive member, positioned on the seating portion, bonding the camera bracket and the camera housing; and a connecting member connecting the first conductive adhesive member and the second conductive adhesive member.

The first conductive adhesive member, the second conductive adhesive member, and the connecting member may be integrated.

The electronic device may further include a rear plate on which the camera bracket is positioned; and a camera window comprising a transparent material, wherein the camera window is positioned on the camera housing and corresponds to the second opening.

According to an aspect of the disclosure, a camera structure for protecting a camera connected to a printed circuit board of an electronic device, the printed circuit board comprising at least one ground portion, includes a camera bracket positioned in a first direction with respect to the camera, wherein the camera bracket comprises a first opening corresponding to a lens of the camera; a conductive adhesive member positioned on the camera bracket and connected to the at least one ground portion of the printed circuit board, the conductive adhesive member comprising a conductive material; and a camera housing forming an exterior portion of the electronic device, wherein the camera housing comprises a metal material and a second opening corresponding to the first opening, and the camera housing is positioned in the first direction with respect to the camera bracket and contacts the conductive adhesive member.

The camera bracket may include at least one first hole, wherein the camera housing may include a first extension positioned in the at least one first hole of the camera bracket, and wherein the conductive adhesive member may include a second extension positioned in the at least one first hole of the camera bracket and in contact with the first extension of the camera housing.

The camera bracket may include a body and a seating portion protruding from the body, and wherein the conductive adhesive member may include a first conductive adhesive member, positioned on the body, bonding the camera bracket and a cover member of the electronic device, the first conductive adhesive member comprising the second extension positioned in the at least one first hole; and a second conductive adhesive member, positioned on the seating portion, bonding the camera bracket and the camera housing.

The camera bracket may include a protrusion protruding from a surface surrounding the at least one first hole and pressing against the first extension of the camera housing and the second extension of the conductive adhesive member, and wherein the camera bracket may include a second hole positioned adjacent to the at least one first hole; and a partition wall partitioning the at least one first hole and the second hole, the protrusion being positioned on the partition wall.

According to an embodiment disclosed herein, charges accumulated in the electronic device may be discharged to the ground portion of the printed circuit board via the camera housing that forms an exterior of the electronic device. In an embodiment, an ESD structure may include a conductive adhesive member that bonds the cover member forming an exterior of the electronic device and the camera housing. For example, charges accumulated in the electronic device may be discharged via the camera housing, the conductive adhesive member, and the ground portion of the printed circuit board.

### BRIEF DESCRIPTION OF THE DRAWINGS

The above and other aspects and features of certain embodiments of the present disclosure are more apparent from the following description taken in conjunction with the accompanying drawings, in which:

In connection with the description of the drawings, the same or similar components may be denoted by the same or similar reference numerals.

FIG. 1 is a block diagram of an electronic device according to an embodiment of the disclosure in a network environment.

FIG. 2A is a front perspective view of an electronic device according to an embodiment of the disclosure.

FIG. 2B is a rear perspective view of the electronic device of FIG. 2A according to an embodiment of the disclosure.

FIG. 3 is an exploded perspective view of the electronic device of FIG. 2A, according to an embodiment of the disclosure.

FIG. 4A is an exploded perspective view of a camera structure according to an embodiment of the disclosure.

FIG. 4B is a cross-sectional view of the electronic device taken along line A-A indicated in FIG. 2A.

FIG. 5A is a front view illustrating a state in which a camera bracket, a conductive adhesive member, and camera housings are assembled according to an embodiment of the disclosure.

FIG. 5B is a view illustrating a state in which the conductive adhesive member and a ground portion of a printed circuit board are in contact, according to an embodiment of the disclosure.

FIG. 6A is a view illustrating assembling the camera bracket and the conductive adhesive member according to an embodiment of the disclosure.

FIG. 6B is a perspective view of a camera housing according to an embodiment of the disclosure.

FIGS. 6C, 6D, and 6E are views each illustrating a state in which a camera housing is assembled to the camera bracket according to an embodiment of the disclosure.

FIG. 7A is a view of a camera housing according to an embodiment different from that illustrated in FIG. 6B.

FIG. 7B is a view of a camera bracket according to an embodiment different from that illustrated in FIG. 6A.

FIGS. 7C and 7D are views each illustrating a state in which the camera housing is assembled to the camera bracket in an embodiment different from that illustrated in FIGS. 6C to 6E.

FIGS. 8A and 8B are views each illustrating assembling a camera bracket and a camera housing according to an embodiment different from that illustrated in FIGS. 6A to 7D.

FIG. 9 is a view illustrating a state in which some components of the electronic device according to an embodiment of the disclosure are removed.

FIGS. 10A to 10C are sectional views taken along line C-C of FIG. 9 and illustrate connection between a frame of the electronic device and a communication module disposed on a printed circuit board.

FIGS. 11A to 11C are views illustrating connection between a frame of the electronic device and a communication module disposed on a printed circuit board in an embodiment different from that illustrated in FIGS. 10A to 10C.

### DETAILED DESCRIPTION

The embodiments described in the disclosure, and the configurations shown in the drawings, are only examples of embodiments, and various modifications may be made without departing from the scope and spirit of the disclosure.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements.

It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

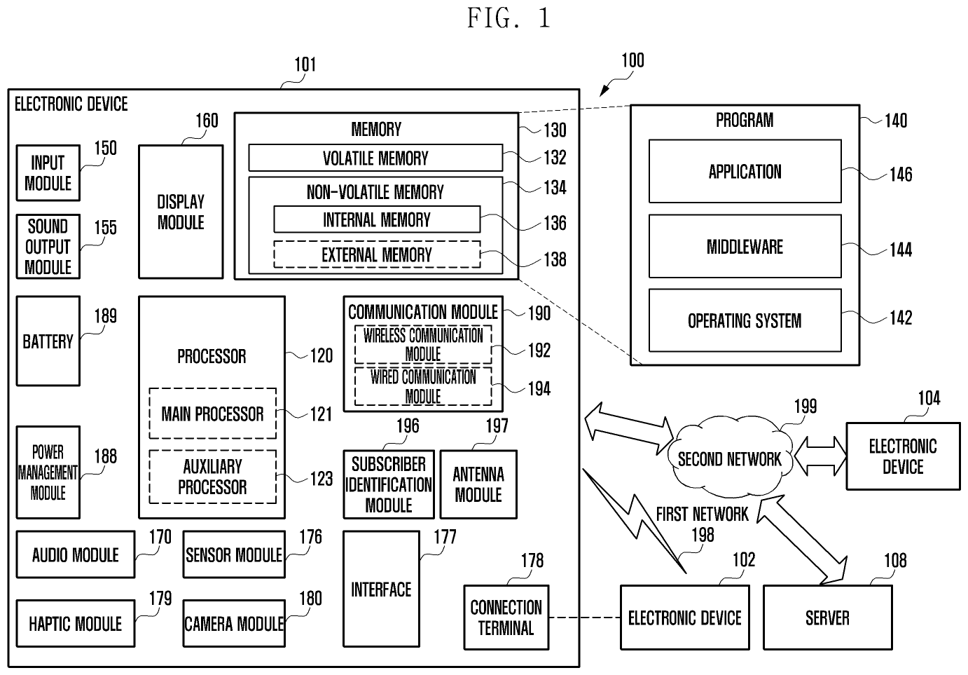

FIG. 1 is a block diagram illustrating an electronic device 01 in a network environment 00 according to various embodiments. Referring to FIG. 1, the electronic device 01 in the network environment 00 may communicate with an electronic device 02 via a first network 98 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197. According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

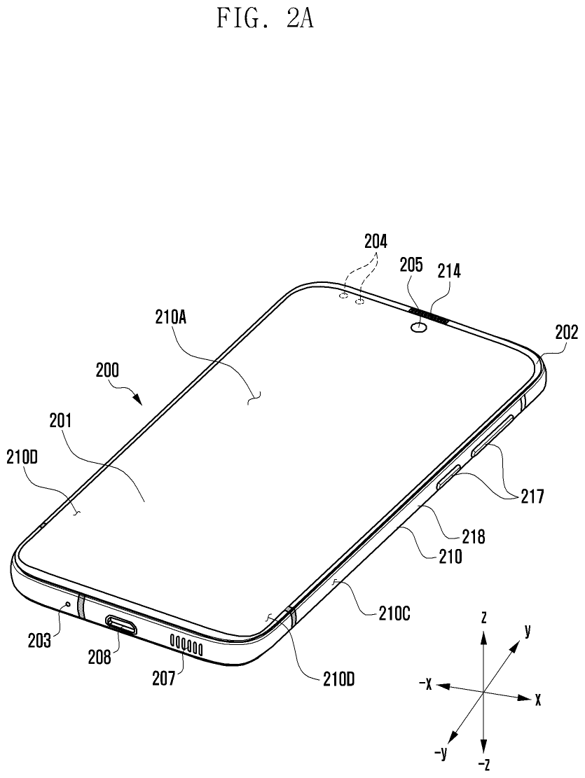

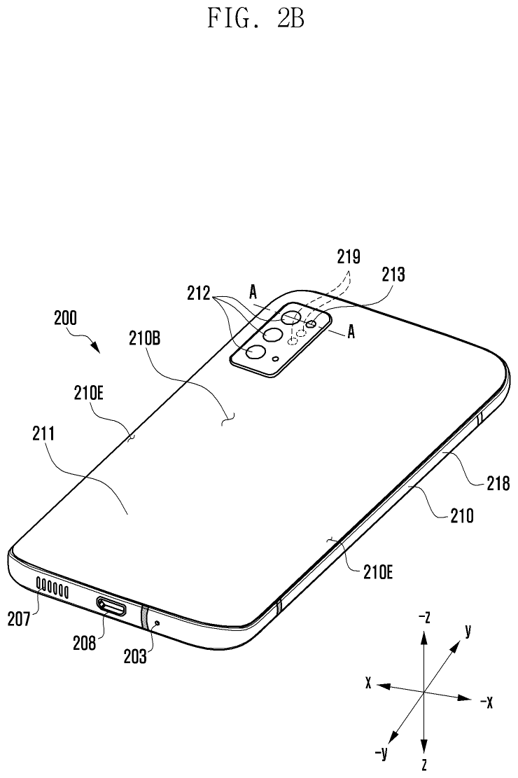

FIG. 2a illustrates a perspective view showing a front surface of a mobile electronic device 300 according to an embodiment, and FIG. 2b illustrates a perspective view showing a rear surface of the mobile electronic device 300 shown in FIG. 2a.

The electronic device 300 of FIGS. 2a and 2b may be at least partially similar to the electronic device 101 of FIG. 1 or may include other embodiments of the electronic device.

Referring to FIGS. 2a and 2b, the mobile electronic device 200 may include a housing 210 that includes a first surface (or front surface) 210A, a second surface (or rear surface) 210B, and a lateral surface 210C that surrounds a space between the first surface 210A and the second surface 210B. The housing 210 may refer to a structure that forms a part of the first surface 210A, the second surface 210B, and the lateral surface 210C. The first surface 210A may be formed of a front plate 202 (e.g., a glass plate or polymer plate coated with a variety of coating layers) at least a part of which is substantially transparent. The second surface 210B may be formed of a rear plate 211 which is substantially opaque. The rear plate 211 may be formed of, for example, coated or colored glass, ceramic, polymer, metal (e.g., aluminum, stainless steel (STS), or magnesium), or any combination thereof. The lateral surface 210C may be formed of a lateral bezel structure (or “lateral member”) 220 which is combined with the front plate 202 and the rear plate 211 and includes a metal and/or polymer. The rear plate 211 and the lateral bezel structure 220 may be integrally formed and may be of the same material (e.g., a metallic material such as aluminum).

The front plate 202 may include two first regions 210D disposed at long edges thereof, respectively, and bent and extended seamlessly from the first surface 210A toward the rear plate 211. Similarly, the rear plate 211 may include two second regions 210E disposed at long edges thereof, respectively, and bent and extended seamlessly from the second surface 210B toward the front plate 202. The front plate 202 (or the rear plate 211) may include only one of the first regions 210D (or of the second regions 210E). The first regions 210D or the second regions 310E may be omitted in part. When viewed from a lateral side of the mobile electronic device 200, the lateral bezel structure 220 may have a first thickness (or width) on a lateral side where the first region 210D or the second region 210E is not included, and may have a second thickness, being less than the first thickness, on another lateral side where the first region 210D or the second region 210E is included.

The mobile electronic device 200 may include at least one of a display 201, audio modules 203, 207 and 214, sensor modules 204 and 219, camera modules 205, 212 and 213, a key input device 217, a light emitting device, and connector holes 208 and 209. The mobile electronic device 200 may omit at least one (e.g., the key input device 217 or the light emitting device) of the above components, or may further include other components.

The display 201 may be exposed through a substantial portion of the front plate 202, for example. At least a part of the display 201 may be exposed through the front plate 302 that forms the first surface 210A and the first region 210D of the lateral surface 210C. Outlines (i.e., edges and corners) of the display 201 may have substantially the same form as those of the front plate 202. The spacing between the outline of the display 201 and the outline of the front plate 202 may be substantially unchanged in order to enlarge the exposed area of the display 201. A recess or opening may be formed in a portion of a display area of the display 201 to accommodate at least one of the audio module 214, the sensor module 204, the camera module 205, and the light emitting device. At least one of the audio module 214, the sensor module 204, the camera module 205, the fingerprint sensor (not shown), and the light emitting element may be disposed on the back of the display area of the display 201. The display 201 may be combined with, or adjacent to, a touch sensing circuit, a pressure sensor capable of measuring the touch strength (pressure), and/or a digitizer for detecting a stylus pen. At least a part of the sensor modules 204 and 219 and/or at least a part of the key input device 217 may be disposed in the first region 210D and/or the second region 210E.

The audio modules 203, 207 and 214 may correspond to a microphone hole 203 and speaker holes 207 and 214, respectively. The microphone hole 203 may contain a microphone disposed therein for acquiring external sounds and, in a case, contain a plurality of microphones to sense a sound direction. The speaker holes 207 and 214 may be classified into an external speaker hole 207 and a call receiver hole 214. The microphone hole 203 and the speaker holes 207 and 314 may be implemented as a single hole, or a speaker (e.g., a piezo speaker) may be provided without the speaker holes 207 and 214.

The sensor modules 204 and 219 may generate electrical signals or data corresponding to an internal operating state of the mobile electronic device 200 or to an external environmental condition. The sensor modules 204 and 219 may include a first sensor module 204 (e.g., a proximity sensor) and/or a second sensor module (e.g., a fingerprint sensor) disposed on the first surface 210A of the housing 210, and/or a third sensor module 219 (e.g., a heart rate monitor (HRM) sensor) and/or a fourth sensor module (e.g., a fingerprint sensor) disposed on the second surface 210B of the housing 210. The fingerprint sensor may be disposed on the second surface 210B as well as the first surface 210A (e.g., the display 201) of the housing 210. The electronic device 200 may further include at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules 205, 212 and 213 may include a first camera device 205 disposed on the first surface 210A of the electronic device 200, and a second camera device 312 and/or a flash 213 disposed on the second surface 210B. The camera module 205 or the camera module 212 may include one or more lenses, an image sensor, and/or an image signal processor. The flash 213 may include, for example, a light emitting diode or a xenon lamp. Two or more lenses (infrared cameras, wide angle and telephoto lenses) and image sensors may be disposed on one side of the electronic device 300.

The key input device 217 may be disposed on the lateral surface 210C of the housing 210. The mobile electronic device 200 may not include some or all of the key input device 217 described above, and the key input device 217 which is not included may be implemented in another form such as a soft key on the display 201. The key input device 217 may include the sensor module disposed on the second surface 210B of the housing 210.

The light emitting device may be disposed on the first surface 210A of the housing 210. For example, the light emitting device may provide status information of the electronic device 200 in an optical form. The light emitting device may provide a light source associated with the operation of the camera module 205. The light emitting device may include, for example, a light emitting diode (LED), an IR LED, or a xenon lamp.

The connector holes 208 and 209 may include a first connector hole 208 adapted for a connector (e.g., a USB connector) for transmitting and receiving power and/or data to and from an external electronic device, and/or a second connector hole 309 adapted for a connector (e.g., an earphone jack) for transmitting and receiving an audio signal to and from an external electronic device.

Some sensor modules 205 of camera modules 205 and 212, some sensor modules 204 of sensor modules 204 and 219, or an indicator may be arranged to be exposed through a display 201. For example, the camera module 205, the sensor module 204, or the indicator may be arranged in the internal space of an electronic device 300 so as to be brought into contact with an external environment through an opening of the display 201, which is perforated up to a front plate 202. In another embodiment, some sensor modules 204 may be arranged to perform their functions without being visually exposed through the front plate 202 in the internal space of the electronic device. For example, in this case, an area of the display 201 facing the sensor module may not require a perforated opening.

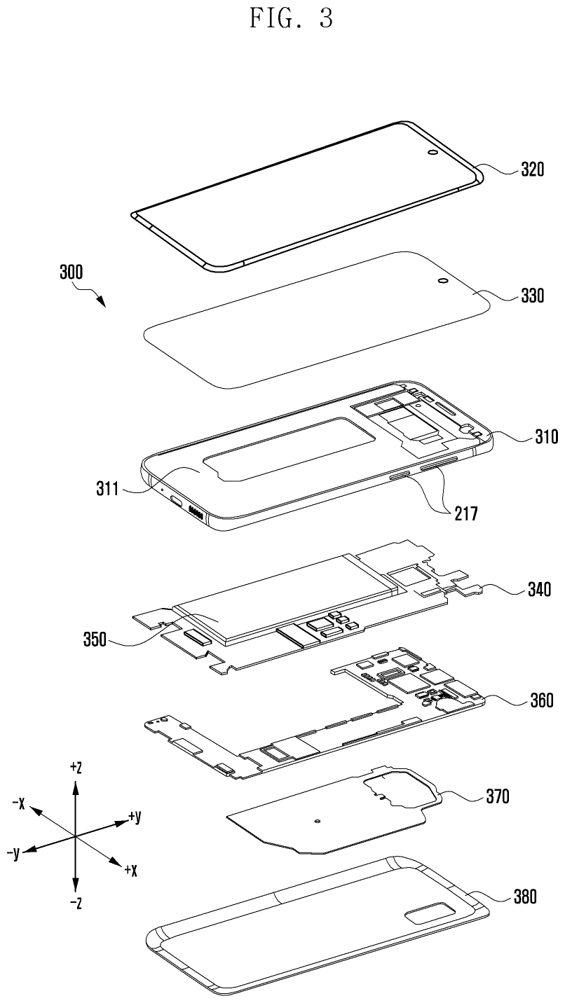

According to an embodiment, the electronic device 200 has a bar-type or plate-type appearance, but the disclosure is not limited thereto. For example, the illustrated electronic device 200 may be a portion of a foldable electronic device, a slidable electronic device, a stretchable electronic device, and/or a rollable electronic device. The terms “foldable electronic device,” “slidable electronic device,” “stretchable electronic device,” and/or “rollable electronic device” may refer to an electronic device in which bending transformation of a display (e.g., the display 330 in FIG. 3) is possible, so that the display can be at least partially folded, wound or rolled, at least partially expanded in area, and/or accommodated inside a housing (e.g., the housing 210 in FIGS. 2A and 2B). The foldable electronic device, the slidable electronic device, the stretchable electronic device, and/or the rollable electronic device may allow a user to use a screen display area in an expanded state by unfolding the display or exposing a greater area of the display to the outside depending on a user's needs.

FIG. 3 is an exploded perspective view of the electronic device of FIG. 2A, according to an embodiment of the disclosure.

The electronic device 300 of FIG. 3 may be at least partially similar to the electronic device 200 of FIGS. 2A and 2B, or may represent another embodiment of the electronic device.

Referring to FIG. 3, the mobile electronic device 300 may include a lateral bezel structure 310, a first support member 3211 (e.g., a bracket), a front plate 302, a display 301, an electromagnetic induction panel, a PCB 340, a battery 350, a second support member 360 (e.g., a rear case), an antenna 370, and a rear plate 311. The mobile electronic device 300 may omit at least one (e.g., the first support member 3211 or the second support member 360) of the above components or may further include another component. Some components of the electronic device 300 may be the same as or similar to those of the mobile electronic device 300 shown in FIG. 2a or FIG. 2b, thus, descriptions thereof are omitted below.

The first support member 3211 is disposed inside the mobile electronic device 300 and may be connected to, or integrated with, the lateral bezel structure 310. The first support member 3211 may be formed of, for example, a metallic material and/or a non-metal (e.g., polymer) material. The first support member 3211 may be combined with the display 301 at one side thereof and also combined with the PCB 340 at the other side thereof. On the PCB 340, a processor, a memory, and/or an interface may be mounted. The processor may include, for example, one or more of a CPU, an AP, a GPU, an ISP, a sensor hub processor, or a CP.

The memory may include, for example, volatile memory or non-volatile memory.

The interface may include, for example, a high definition multimedia interface (HDMI), a USB interface, a secure digital (SD) card interface, and/or an audio interface. The interface may electrically or physically connect the mobile electronic device 300 with an external electronic device and may include a USB connector, an SD card/multimedia card (MMC) connector, or an audio connector.

The battery 350 is a device for supplying power to at least one component of the mobile electronic device 300, and may include, for example, a non-rechargeable primary battery, a rechargeable secondary battery, or a fuel cell. At least a part of the battery 350 may be disposed on substantially the same plane as the PCB 340. The battery 350 may be integrally disposed within the mobile electronic device 300, and may be detachably disposed from the mobile electronic device 300.

The antenna 370 may be disposed between the rear plate 311 and the battery 350. The antenna 370 may include, for example, a near field communication (NFC) antenna, a wireless charging antenna, and/or a magnetic secure transmission (MST) antenna. The antenna 370 may perform short-range communication with an external device, or transmit and receive power required for charging wirelessly. An antenna structure may be formed by a part or combination of the lateral bezel structure 310 and/or the first support member 3211.

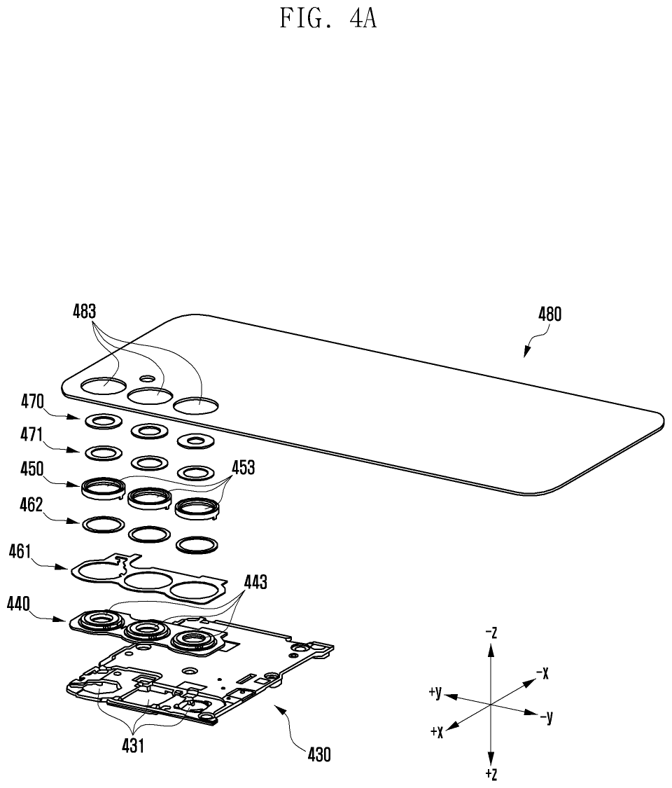

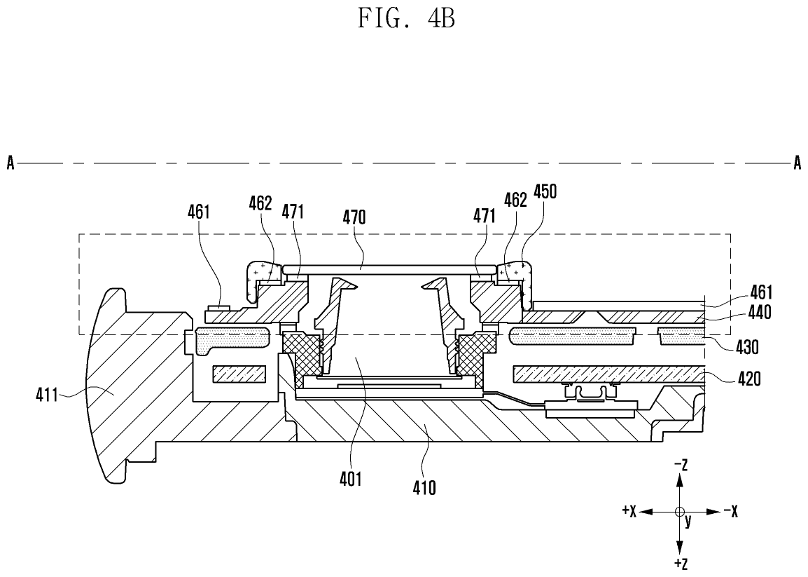

FIG. 4A is an exploded perspective view of a camera structure according to an embodiment of the disclosure. FIG. 4B is a cross-sectional view of the electronic device taken along line A-A indicated in FIG. 2A.

According to an embodiment of the disclosure, an electronic device 400 (e.g., the electronic device 101 of FIG. 1, the electronic device 200 of FIG. 2A, and/or the electronic device 300 of FIG. 3) may include a camera structure. The camera structure may include camera modules 401 (e.g., cameras, the camera module 180 of FIG. 1, or the camera module 212 of FIG. 2B) and a mechanical component that supports the camera modules. In an embodiment, the camera structure of the electronic device 400 may include the camera modules 401, a rear plate 430, a camera bracket 440, camera housings 450, and camera windows 470. At least one of the components of the camera structure described above may be omitted or added. The shape of the camera structure is not limited to what is illustrated in the drawings.

According to an embodiment, as illustrated in FIGS. 4A and 4B, the electronic device 400 may be assembled in the order of the camera modules 401, the rear plate 430, the camera bracket 440, a conductive adhesive member 460 (e.g., a first conductive adhesive member 461 and a second conductive adhesive member 462), the camera housings 450, the camera windows 470, and a cover member 480 (e.g., the rear surface plate 211 of FIG. 2B or the rear surface plate 380 of FIG. 3).

In an embodiment, the camera modules 401 may each include an image sensor configured to convert light reflected from an object into an electrical signal. The image sensor may be, for example, a sensor such as a charge coupled device (CCD) or a complementary metal oxide semiconductor (CMOS). In an embodiment, the camera modules 401 may be cameras of different types or cameras performing different functions. For example, the camera modules 401 may have different angles of view. In an embodiment, the camera modules 401 may each include a lens (not illustrated) into which light reflected from an object is introduced. The camera modules 401 may be at least partially inserted through the openings 431 of the rear plate 430, the first openings 443 of the camera bracket 440, and the second openings 453 of the camera housings 450. A camera window 470, at least a portion of which is made of a material having high light transmittance, may be disposed in each of the second openings 453 of the camera housings 450. As a lens is disposed to face each of the camera windows 470, the camera modules 401 may detect light reflected from an object.

In an embodiment, referring to FIGS. 4A and 4B, the rear plate 430 may support at least a portion of the printed circuit board 420 (e.g., the board 340 of FIG. 3) and the camera modules 401. In an embodiment, the rear plate 430 may be disposed in a first direction (e.g., the −Z direction with reference to FIG. 4B) with respect to the printed circuit board 420 and the camera module 401 to support the printed circuit board 420 and the camera module 401 in a second direction (e.g., the +Z direction with reference to FIG. 4B) opposite to the first direction. In an embodiment, the rear plate 430 may include openings 431 through each of which at least a portion (e.g., a lens) of one of the camera modules 401 passes. The rear plate 430 may be positioned in the first direction with respect to the camera modules 401 to allow the camera modules 401 to partially pass through the rear plate.

In an embodiment, referring to FIGS. 4A and 4B, the camera bracket 440 may be disposed in the first direction with respect to the rear plate 430 to at least partially surround the camera modules 401. In an embodiment, the camera bracket 440 may include first openings 443 through each of which at least a portion of one of the camera modules 401 passes. The camera bracket 440 may be disposed in the first direction with respect to the rear plate 430 such that the first openings 443 corresponds to the openings 431 of the rear plate 430. In an embodiment, a surface of the camera bracket 440 that surrounds the first openings 443 may partially surround the camera modules 401 positioned in the first openings 443. Accordingly, the camera modules 401 may be protected from an external impact by the camera bracket 440.

In an embodiment, referring to FIG. 4B, the camera bracket 440 may include a body 441 and seating portions 442 protruding in the first direction (e.g., the −Z direction with reference to FIG. 4B) with respect to the body 441. In an embodiment, each camera housing 450 may include a second opening 453 into which a portion of one of the camera modules 401 is inserted. The camera housings 450 may be disposed on the seating portions 442 of the camera bracket 440 such that the second openings 453 correspond to the first openings 443 of the camera bracket 440. In an embodiment, the camera housings 450 may have a ring shape and may be disposed on the seating portions 442 of the camera bracket 440.

In an embodiment, referring to FIG. 4B, at least a portion of each camera housings 450 may form an exterior, e.g., a first exterior portion, of the electronic device 400. In an embodiment, the camera housings 450 may be exposed to the outside of the electronic device 400 through third openings 483 formed in a cover housing 410 (e.g., the housing 210 of FIG. 2A).

In an embodiment, referring to FIGS. 4A and 4B, the camera windows 470 for protecting the lenses of the camera modules 401 may be disposed in the second openings 453 of the camera housings 450. The camera windows 470 may be coupled to the camera housings 450 via window adhesive members 471. The camera windows 470 may be exposed to the outside of the electronic device 400. The camera windows 470 may be at least partially formed of a material having high light transmittance. For example, the camera windows 470 may be made of substantially transparent glass or synthetic resin. The camera windows 470 may block foreign substances from entering the inside of the camera modules 401. The camera windows 470 may be exposed to the external environment, and thus may be made of a material having good durability (e.g., hardness, strength, corrosion resistance).

According to an embodiment, the cover member 480 may be made of a non-metallic material such as synthetic resin, ceramic, or engineering plastic. When the cover member 480 is made of a non-conductive material, charges may be accumulated on the cover member 480. In particular, the cover member 480 may be a portion frequently touched by a user when holding the electronic device 400 and may be a portion where charges tends to be accumulated. Charges may be accumulated on other non-metallic structural components and the cover member 480 may form the exterior, e.g., a second exterior portion, of the electronic device 400. In an embodiment, when a path E through which the charges accumulated on the cover member 480 can flow is not provided, electrostatic discharge (ESD) may occur. The ESD phenomenon may refer to an electrical phenomenon in which charges accumulated due to various factors are instantaneously transferred to another portion. The ESD may involve a high voltage. Accordingly, when ESD occurs in an electronic component, the electronic component may be damaged. Such damage may cause problems in which the electronic device 400 may not function properly or the performance of the electronic device may be deteriorated. For example, charges accumulated outside the electronic device 400 may be at least partially introduced into the electronic device 400 through structural components made of a conductive material and disposed inside the electronic device 400. The charges may be introduced into the electronic device 400 through gaps in the structural components. When a path for guiding the charges introduced into the electronic device 400 to ground (GND) is not formed, the charges may be discharged to electronic components such as the camera modules 401. Accordingly, this may cause malfunction of the electronic components. In the foregoing description, it is assumed that the cover member 480 is made of a non-metallic material, but the material of the cover member 480 may not be necessarily limited to a non-metallic material. In an embodiment, the cover member 480 may be made of a metal material. Even when the cover member 480 is made of a metal material, if a path for the electrostatic charges generated outside the electronic device 400 is not provided, damage to electronic components may occur.

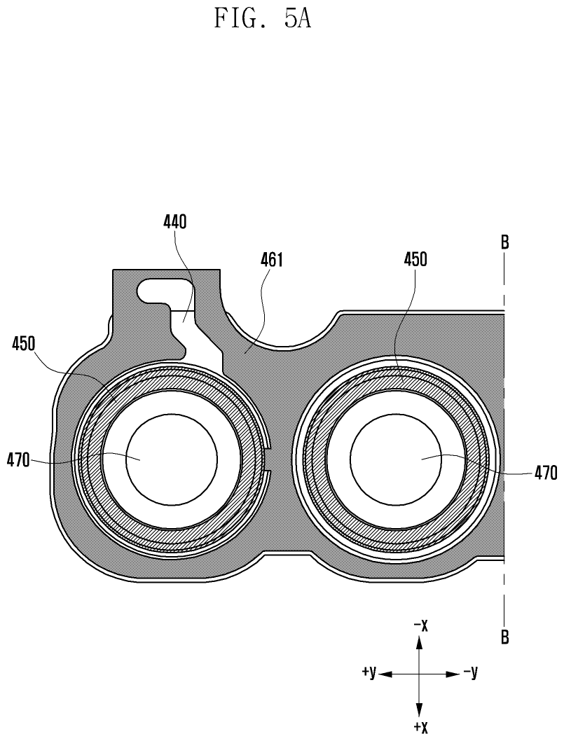

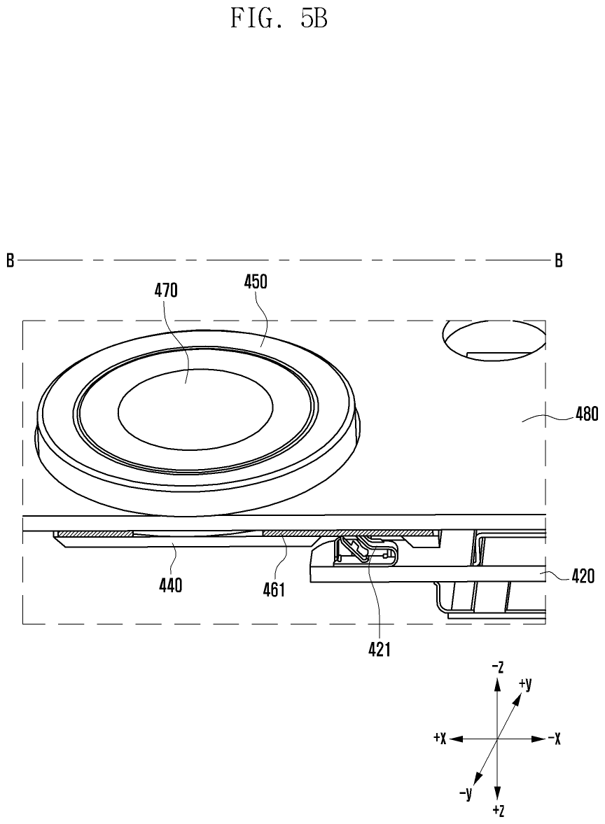

According to an embodiment of the disclosure, a path E through which the accumulated charges flow may be provided. In an embodiment, the camera housings 450 may be made of a conductive material such as a metal. The camera housings 450 may be electrically connected to a ground portion 421 of the printed circuit board 420 via a conductive adhesive member 460 (e.g., the conductive adhesive member 460 illustrated in FIGS. 4B and 5A) used to bond the camera bracket 440 and the camera housings 450. The accumulated charges may be guided to the ground portion 421, which has a relatively low potential. The charges accumulated outside the electronic device 400 may be discharged to the ground portion 421 of the printed circuit board 420 via the camera housings 450 and the conductive adhesive member 460. Accordingly, damage to the electronic components caused by the charges may be mitigated or prevented.

Meanwhile, when the camera housings 450 and the camera brackets 440 are made of a metal material, the manufacturing cost of the electronic device 400 may increase. Accordingly, the camera housings 450 forming an exterior of the electronic device 400 may be made of a metal material, and the camera bracket 440 may be made of a non-metallic material such as synthetic resin, ceramic, or engineering plastic. The camera housings 450 made of a metal material may be electrically connected to the ground portion 421 of the printed circuit board 420 via the conductive adhesive member 460. Therefore, the electronic device 400 according to the disclosure may reduce the production cost of the camera structure and may form a discharge path E for transferring the accumulated charges to the ground portion 421 using the camera housings 450 and the conductive adhesive member 460.

Hereinafter, the structural relationship among the camera housings 450, the camera bracket 440, the conductive adhesive member 460, and the ground portion 421 of the printed circuit board 420 will be described in detail.

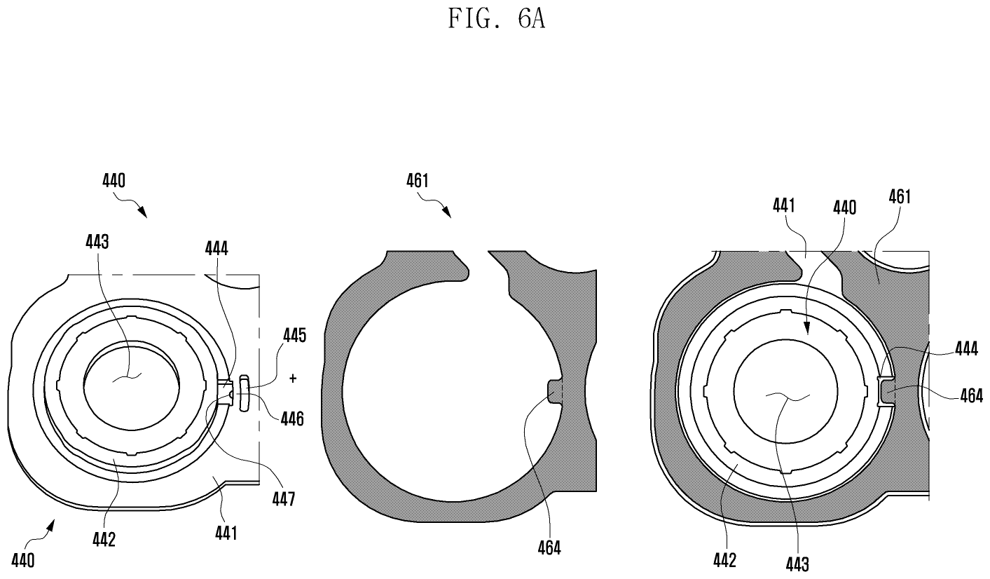

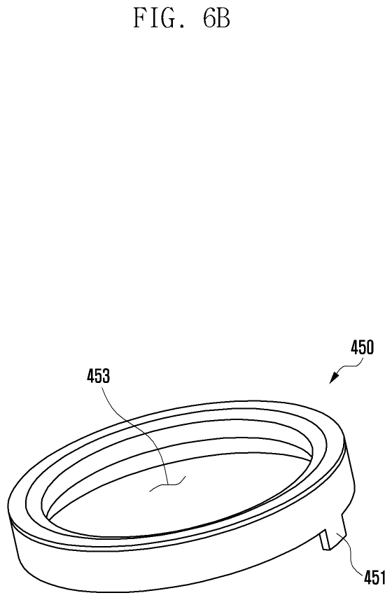

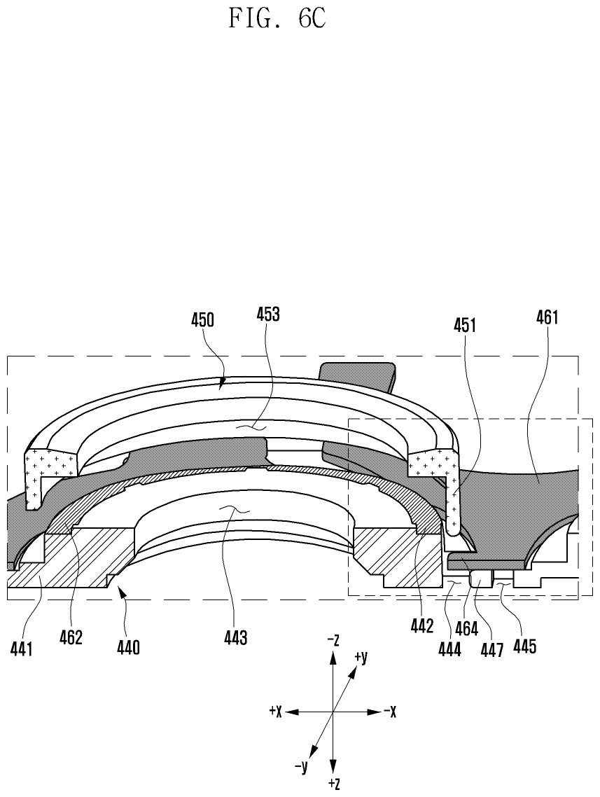

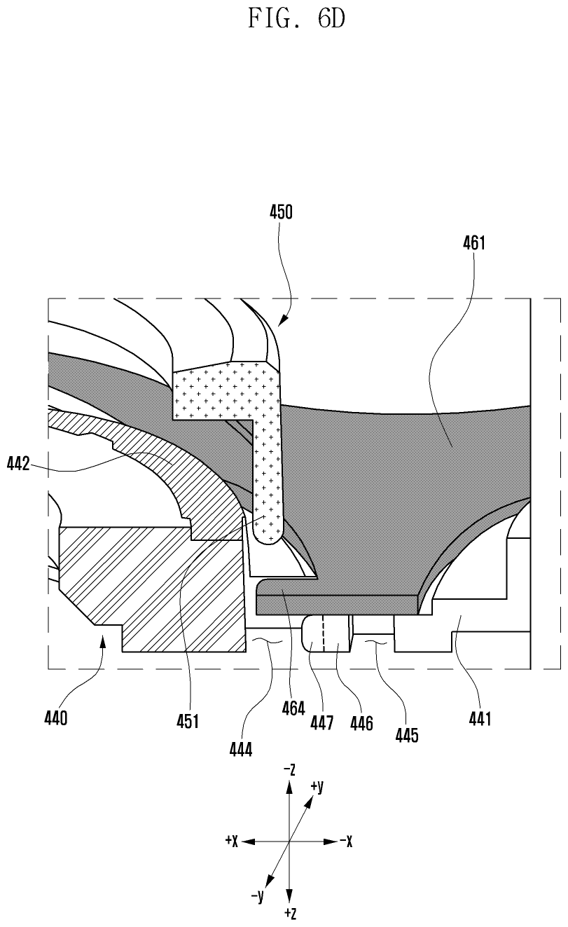

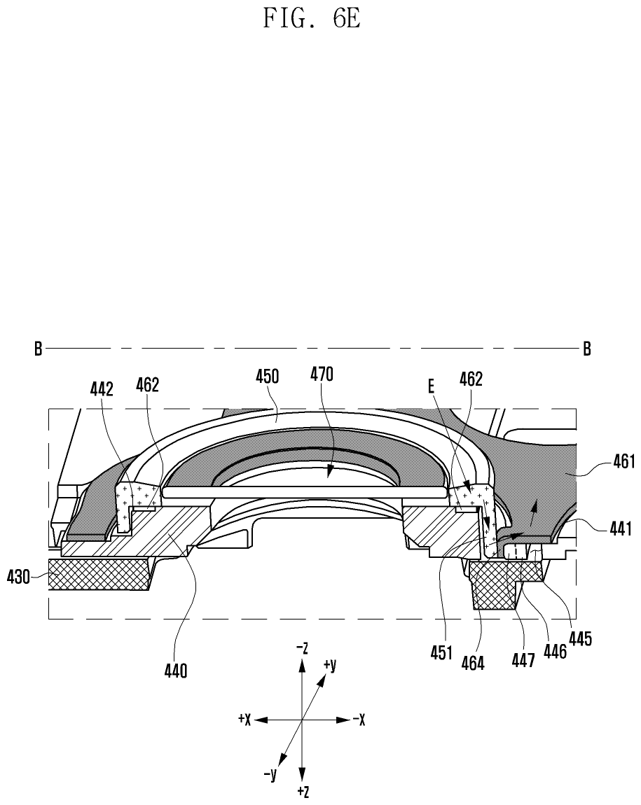

FIG. 5A is a front view illustrating a state in which a camera bracket, a conductive adhesive member, and camera housings are assembled according to an embodiment of the disclosure. FIG. 5B is a view illustrating a state in which the conductive adhesive member and the ground portion of the printed circuit board are in contact, according to an embodiment of the disclosure. FIG. 6A is a view illustrating assembling the camera bracket and the conductive adhesive member according to an embodiment of the disclosure. FIG. 6B is a perspective view of a camera housing according to an embodiment of the disclosure. FIGS. 6C, 6D, and 6E are views each illustrating a state in which a camera housing is assembled to the camera bracket according to an embodiment of the disclosure.

In an embodiment, as illustrated in FIGS. 4B and 5A, a conductive adhesive member 460 may be disposed on the camera bracket 440. The conductive adhesive member 460 may include a first conductive adhesive member 461 bonded to the body 441 of the camera bracket 440 and a second conductive adhesive member 462 bonded to a seating portion 442 of the camera bracket 440. In an embodiment, the conductive adhesive member 460 may include adhesive layers (not illustrated) disposed on both surfaces. In an embodiment, the cover member 480 (e.g., the rear surface plate 211 of FIG. 2B or the rear surface plate 380 of FIG. 3) may be disposed in the first direction (e.g., the −Z direction with reference to FIG. 4A) with respect to the camera bracket 440 and may be bonded to the camera bracket 440 via the first conductive adhesive member 461. In an embodiment, the camera housing 450 may be disposed on the seating portion 442 of the camera bracket 440 and may be bonded to the camera bracket 440 via the second conductive adhesive member 462.

In an embodiment, referring to FIG. 5B, the conductive adhesive member 460 may be connected to the ground portion 421 of the printed circuit board 420 (e.g., the board 340 of FIG. 3). For example, the first conductive adhesive member 461 of the conductive adhesive member 460 may be in contact with the ground portion 421 of the printed circuit board 420. Accordingly, the ground portion 421 and the first conductive adhesive member 461 may be electrically connected.

According to an embodiment, the first conductive adhesive member 461 and the second conductive adhesive member 462 may be separately disposed on the camera bracket 440. For example, the first conductive adhesive member 461 disposed on the body 441 of the camera bracket 440 and the second conductive adhesive member 462 disposed on the seating portion 442 of the camera bracket 440 may be in a disconnected state. In such a case, the camera bracket 440 may require a configuration that connects the first conductive adhesive member 461, which is in contact with the ground portion 421 of the printed circuit board 420, and the camera housing 450 made of a conductive material. This will be described in detail below.

According to an embodiment, as illustrated in FIG. 6A, the camera bracket 440 may include at least one first hole 444. Referring to FIG. 6B, the camera housing 450 may include a first extension 451 inserted into the first hole 444 of the camera bracket 440. The first conductive adhesive member 461 of the conductive adhesive member 460 may include a second extension 464 inserted into the first hole 444 of the camera bracket 440. The contact between the camera housing 450 and the first conductive adhesive member 461 may be made in the following manner. Referring to FIGS. 6A, 6C, and 6D, the first conductive adhesive member 461 may be seated on the camera bracket 440 such that the second extension 464 is positioned in the first hole 444 of the camera bracket 440. Subsequently, the camera housing 450 may be disposed on the seating portion 442 of the camera bracket 440 such that the first extension 451 is inserted into the first hole 444. As illustrated in FIGS. 6D and 6E, as the first extension 451 is inserted into the first hole 444, the second extension 464 may be inserted into the first hole 444 of the camera bracket 440 together with the first extension 451 of the camera housing 450. The first extension 451 of the camera housing 450 and the second extension 464 of the first conductive adhesive member 461 may come into contact with each other in the first hole 444 of the camera bracket 440. Accordingly, the camera housing 450 and the first conductive adhesive member 461 may be electrically connected.

According to an embodiment, in a portion of the second extension 464 that includes a surface in contact with the first extension 451, the adhesive layer may be removed, or a portion of the surface in contact with the first extension 451 may be coated with a non-adhesive material. When assembling or disassembling the camera housing 450 to or from the camera bracket 440, the first extension 451 and the second extension 464 may not be bonded to each other, allowing for easier assembly or disassembly.

According to an embodiment, as illustrated in FIGS. 6A, 6C, 6D, and 6E, the camera bracket 440 may include a protrusion 447 positioned in the first hole 444. In an embodiment, the protrusion 447 may protrude toward the first hole 444 from a surface of the camera bracket 440 that surrounds the first hole 444. The protrusion 447 may press the first extension 451 of the camera housing 450 and the second extension 464 of the first conductive adhesive member 461 inserted into the first hole 444. For example, as the first extension 451 of the camera housing 450 and the second extension 464 of the first conductive adhesive member 461 are inserted into the first hole 444 of the camera bracket 440, the first and second extensions may be pressed by the protrusion 447. Accordingly, the first extension 451 and the second extension 464 may be pressed and held in contact with each other by the protrusion 447.

According to an embodiment, the first extension 451 of the camera housing 450 may be inclined at a predetermined angle with respect to the first direction. In an embodiment, the first extension 451 of the camera housing 450 may spread toward the protrusion 447 of the camera bracket 440 by elasticity, while inserted into the first hole 444 of the camera bracket 440. In such a case, the second extension 464 of the first conductive adhesive member 461 may be pressed toward the protrusion 447 of the camera bracket 440 by the first extension 451 of the camera housing 450. The first extension 451 and the second extension 464 may be pressed and held in contact with each other by the protrusion 447. In some embodiments, the first extension 451 of the camera housing 450 may be inclined at a predetermined angle with respect to the first direction, in a direction away from the protrusion 447 of the camera bracket 440. For example, the first extension 451 of the camera housing 450 may have a constricted shape that surrounds at least a portion of the camera bracket 440. Accordingly, the physical coupling force between the camera housing 450 and the camera bracket 440 may be increased.

In an embodiment, since the camera housing 450 is exposed to the outside of the electronic device 400 (e.g., the electronic device 101 of FIG. 1, the electronic device 200 of FIG. 2A, and/or the electronic device 300 of FIG. 3), the camera housing may be made of a metal material having a certain level of rigidity. On the other hand, the camera bracket 440 may be made of a plastic material having lower rigidity than the camera housing 450. In such a case, when inserted into the first hole 444 of the camera bracket 440, the first extension 451 of the camera housing 450 may press a surface surrounding the first hole 444 of the camera bracket 440, causing damage to the camera bracket 440. According to an embodiment of the disclosure, as illustrated in FIGS. 6A, 6C, 6D, and 6E, the camera bracket 440 may include a second hole 445 disposed adjacent to the first hole 444, and a partition wall 446 that partitions the first hole 444 and the second hole 445. The protrusion 447 of the camera bracket 440 may protrude from the partition wall 446 toward the first hole 444. As described above, the first extension 451 of the camera housing 450 may press the partition wall 446 of the camera bracket 440 when inserted into the first hole 444 of the camera bracket 440. In this case, the partition wall 446 of the camera bracket 440 may retract toward the second hole 445 by elasticity. Accordingly, the camera bracket 440 may not be damaged even when the first extension 451 of the camera housing 450 is inserted into the first hole 444.

According to an embodiment, the first conductive adhesive member 461 may be disposed such that at least a portion thereof is spaced apart from the camera bracket 440. In an embodiment, the second extension 464 of the first conductive adhesive member 461 may be spaced apart from the camera bracket 440 in the first direction (e.g., the −Z direction with reference to FIG. 6C). In such a case, the second extension 464 of the first conductive adhesive member 461 may move while being in contact with the first extension 451 of the camera housing 450.

In an embodiment not illustrated in the drawings, the camera bracket 440 may include a plurality of first holes 444. The camera housing 450 may include a plurality of first extensions 451, and the first conductive adhesive member 461 may include a plurality of second extensions 464. In an embodiment, the first extensions 451 may be formed on the camera housing 450 based on the number of first holes 444. For example, the camera housing 450 may include a plurality of first extensions 451 inserted into the plurality of first holes 444. In an embodiment, the plurality of first extensions 451 may face each other, and in some embodiments, the first extensions 451 may be arranged on the camera housing 450 at regular intervals to be inserted into the first holes 444. In an embodiment, the first conductive adhesive member 461 may include a plurality of second extensions 464 corresponding to the first extensions 451. In an embodiment, the plurality of second extensions 464 may face each other. In some embodiments, the plurality of second extensions 464 may be arranged at regular intervals and inserted into the plurality of first holes 444. The plurality of first extensions 451 and the plurality of second extensions 464 may be respectively positioned in the plurality of first holes 444 to come into contact with each other. In such a case, the contact areas among the camera housing 450, the first conductive adhesive member 461, and the ground portion 421 of the printed circuit board 420, which constitute a discharge path E for electrostatic charge, may be increased. Accordingly, the electrical connection among the camera housing 450, the first conductive adhesive member 461, and the ground portion 421 of the printed circuit board 420 may be stably achieved.

According to an embodiment of the disclosure, as illustrated in FIG. 6E, at least a portion of the camera housing 450 may form a portion of a rear exterior of the electronic device 400. The camera housing 450 may be made of a conductive material such as a metal. In an embodiment, the camera housing 450 may be electrically connected to the ground portion 421 of the printed circuit board 420 via the first conductive adhesive member 461 that is in contact with the ground portion 421 of the printed circuit board 420. In an embodiment, the first conductive adhesive member 461 may be disposed on the body 441 of the camera bracket 440 such that the second extension 464 is positioned in the first hole 444 of the camera bracket 440. The camera housing 450 may be disposed on the seating portion 442 of the camera bracket 440 such that the first extension 451 is inserted into the first hole 444 of the camera bracket 440. As the first extension 451 of the camera housing 450 is inserted into the first hole 444 of the camera bracket 440, at least a portion of the second extension 464 of the first conductive adhesive member 461 may be bent and inserted into the first hole 444. The second extension 464 of the first conductive adhesive member 461 may be in contact with the first extension 451 of the camera housing 450 and positioned in the first hole 444 of the camera bracket 440. Accordingly, charges accumulated outside the electronic device 400 may be discharged through the exterior of the camera housing 450, the first extension 451 of the camera housing 450, the second extension 464 of the first conductive adhesive member 461, and the ground portion 421 of the printed circuit board 420. As the accumulated charges move to the ground portion 421 having a relatively low potential, accumulation of charges may not occur. Since the accumulated charges move to the ground portion 421, the charges may not be discharged to electronic components. Accordingly, damage to the electronic components may be prevented.

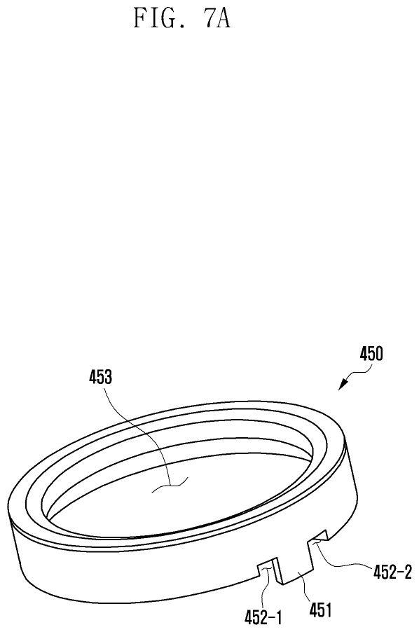

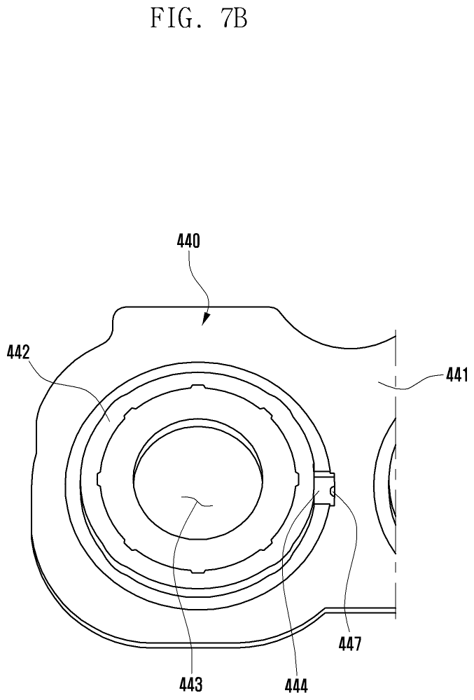

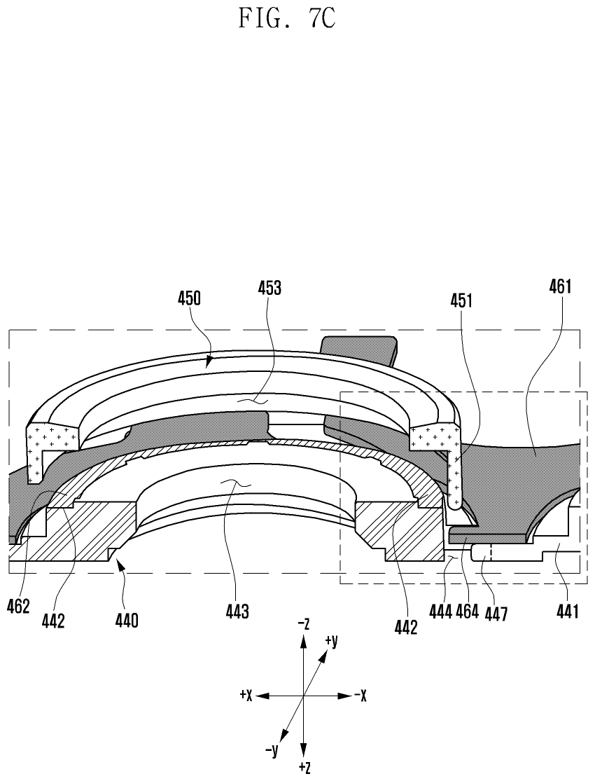

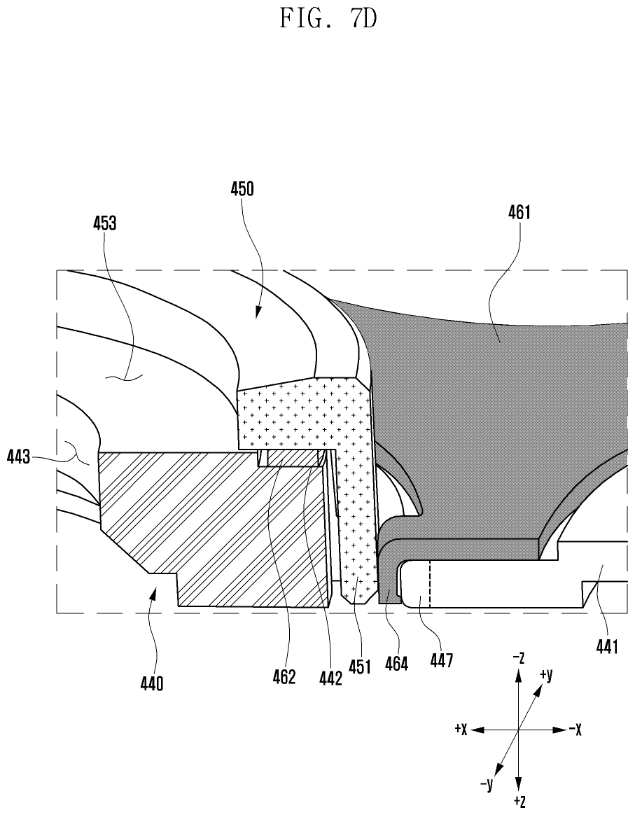

FIG. 7A is a view of a camera housing according to an embodiment different from that illustrated in FIG. 6B. FIG. 7B is a view of a camera bracket according to an embodiment different from that illustrated in FIG. 6A. FIGS. 7C and 7D are views each illustrating a state in which the camera housing is assembled to the camera bracket in an embodiment different from that illustrated in FIGS. 6C to 6E.

The camera housing 450 and the camera bracket 440 described below may be a camera housing 450 and a camera bracket 440 of an embodiment different from those described with reference to FIGS. 5A to 6E. The camera housing 450 and the camera bracket 440 described below may have substantially the same configuration as the camera bracket 440 and the camera housing 450 described with reference to FIGS. 5A to 6E, except that some components are added or omitted. Accordingly, the same reference numerals as those used in FIGS. 5A to 6E will be used for the camera bracket 440 and the camera housing 450 described below, and redundant descriptions will be omitted.

According to an embodiment, as illustrated in FIG. 7A, the camera housing 450 may include a first groove 452-1 at one side of the first extension 451 and a second groove 452-2 formed at the other side of the first extension 451. In an embodiment, the first extension 451 may have an increased physical length through the first groove 452-1 and the second groove 452-2 formed in the camera housing 450. As described above, since the camera housing 450 is exposed to the outside of the electronic device 400 (e.g., the electronic device 101 of FIG. 1, the electronic device 200 of FIG. 2A, and/or the electronic device 300 of FIG. 3), the camera housing may be made of a metal material having a certain level of rigidity. On the other hand, the camera bracket 440 may be made of a plastic material having lower rigidity than the camera housing 450. In such a case, when inserted into the first hole 444 of the camera bracket 440, the first extension 451 of the camera housing 450 may press a surface surrounding the first hole 444 of the camera bracket 440, causing damage to the camera bracket 440. According to an embodiment of the disclosure, the physical length of the first extension 451 of the camera housing 450 may be increased through the first groove 452-1 and the second groove 452-2 formed at both sides thereof. As the length of the first extension 451 increases, the first extension 451 may be more easily bent. Accordingly, when inserted into the first hole 444 of the camera bracket 440 illustrated in FIG. 7B, the first extension 451 may come into contact with a surface surrounding the first hole 444 and retract by elasticity. Accordingly, the camera bracket 440 may not be damaged even when the first extension 451 of the camera housing 450 is inserted into the first hole 444.

According to an embodiment of the disclosure, as illustrated in FIGS. 7C and 7D, the camera housing 450 may be disposed on the seating portion 442 of the camera bracket 440 such that the first extension 451 is inserted into the first hole 444 of the camera bracket 440. The first conductive adhesive member 461 may be bonded to the body 441 of the camera bracket 440 such that the second extension 464 is positioned in the first hole 444 of the camera bracket 440. As the first extension 451 of the camera housing 450 is inserted into the first hole 444 of the camera bracket 440, at least a portion of the second extension 464 of the first conductive adhesive member 461 may be bent and inserted into the first hole 444. The second extension 464 of the first conductive adhesive member 461 may be in contact with the first extension 451 of the camera housing 450 and positioned in the first hole 444 of the camera bracket 440. Accordingly, charges accumulated outside the electronic device 400 may be discharged to the ground portion 421 of the printed circuit board 420 (e.g., the board 340 of FIG. 3) through the exterior of the camera housing 450, the first extension 451 of the camera housing 450, and the second extension 464 of the first conductive adhesive member 461. As the accumulated charges move to the ground portion 421 having a relatively low potential, accumulation of charges may not occur. Since the accumulated charges move to the ground portion 421, the charges may not be discharged to electronic components, and damage to the electronic components may be prevented.

In an embodiment not illustrated in the drawings, the camera bracket 440 may include a plurality of first holes 444. The camera housing 450 may include a plurality of first extensions 451, and the first conductive adhesive member 461 may include a plurality of second extensions 464. In an embodiment, the first extensions 451 may be formed on the camera housing 450 based on the number of first holes 444. For example, the camera housing 450 may include a plurality of first extensions 451 inserted into the plurality of first holes 444. In an embodiment, the plurality of first extensions 451 may face each other. In some embodiments, the first extensions 451 may be arranged on the camera housing 450 at regular intervals to be inserted into the first holes 444. In an embodiment, the first conductive adhesive member 461 may include a plurality of second extensions 464 corresponding to the first extensions 451. In an embodiment, the plurality of second extensions 464 may face each other, and in some embodiments, the plurality of second extensions 464 may be arranged at regular intervals to be inserted into the plurality of first holes 444. The plurality of first extensions 451 and the plurality of second extensions 464 may be respectively positioned in the plurality of first holes 444 to come into contact with each other. In such a case, the contact areas among the camera housing 450, the first conductive adhesive member 461, and the ground portion 421 of the printed circuit board 420, which constitute a discharge path E for electrostatic charge, may be increased. Accordingly, the electrical connection among the camera housing 450, the first conductive adhesive member 461, and the ground portion 421 of the printed circuit board 420 may be stably achieved.

Meanwhile, the second extensions 464 may have an adhesive layer removed in a partial area including a surface in contact with the first extension 451, or may be coated with a non-adhesive material. When assembling or disassembling the camera housing 450 to or from the camera bracket 440, the first extension 451 and the second extension 464 may not be bonded to each other, allowing for easier assembly or disassembly.

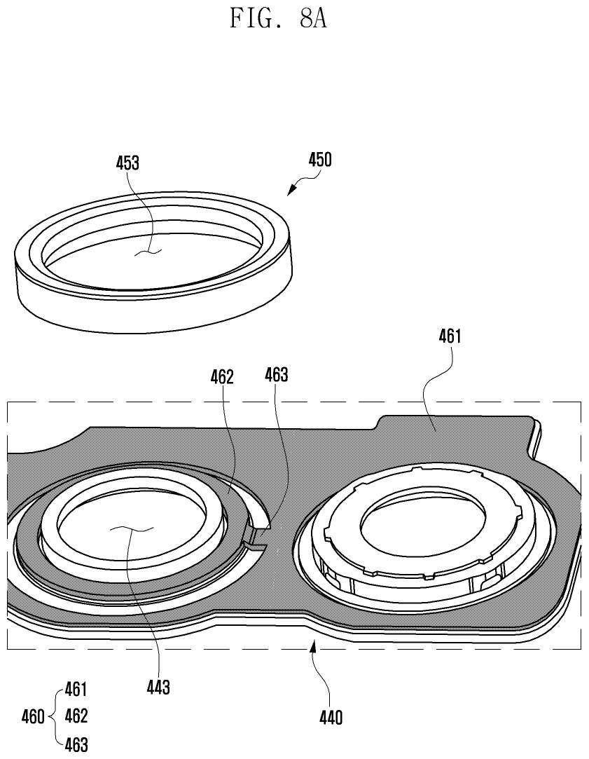

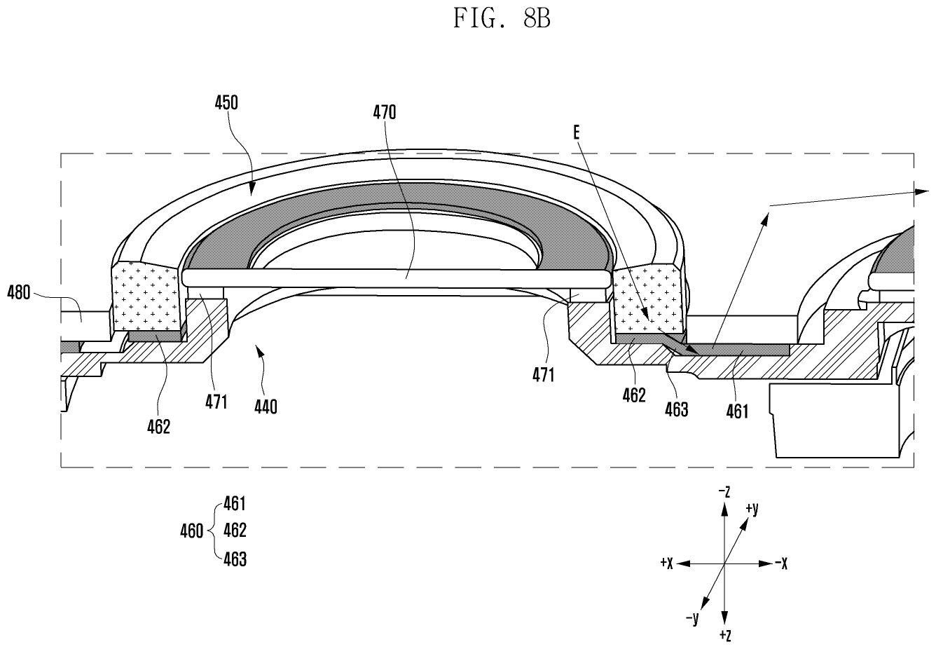

FIGS. 8A and 8B are views illustrating assembling a camera bracket 440 and a camera housing 450 according to an embodiment different from that illustrated in FIGS. 6A to 7D.

The camera housing 450 and the camera bracket 440 described below may be a camera housing 450 and a camera bracket 440 of an embodiment different from those described with reference to FIGS. 5A to 7D. The camera housing 450 and the camera bracket 440 described below may have substantially the same configuration as the camera bracket 440 and the camera housing 450 described with reference to FIGS. 5A to 7D, except that some components are added or omitted. Accordingly, the same reference numerals as those used in FIGS. 5A to 7D will be used for the camera bracket 440 and the camera housing 450 described below, and redundant descriptions will be omitted.

According to an embodiment, as illustrated in FIG. 8A, a conductive adhesive member 460 may include a first conductive adhesive member 461, a second conductive adhesive member 462, and a connecting member 463. The first conductive adhesive member 461 may be a portion of the conductive adhesive member 460 that is disposed on the body 441 of the camera bracket 440. The second conductive adhesive member 462 may be a portion of the conductive adhesive member 460 that is disposed on the seating portion 442 of the camera bracket 440. The connecting member 463 may be a component that physically connects the first conductive adhesive member 461 and the second conductive adhesive member 462. The first conductive adhesive member 461, the second conductive adhesive member 462, and the connecting member 463 described above are distinguished for convenience of description, and may not be physically separated components. For example, the first conductive adhesive member 461, the second conductive adhesive member 462, and the connecting member 463 may be integrated.

According to an embodiment, as illustrated in FIG. 8A, the camera housing 450 may not include the first extension 451 described with reference to FIGS. 5A to 7D. The camera housing 450 may be disposed on the seating portion 442 of the camera bracket 440 and may be in contact with the second conductive adhesive member 462. In this case, the camera housing 450, the second conductive adhesive member 462, the connecting member 463, the first conductive adhesive member 461, and the ground portion 421 of the printed circuit board 420 may be electrically connected. Accordingly, charges accumulated outside the electronic device 400 (e.g., the electronic device 101 of FIG. 1, the electronic device 200 of FIG. 2A, and/or the electronic device 300 of FIG. 3) may be discharged to the ground portion 421 of the printed circuit board 420 via the camera housing 450, the second conductive adhesive member 462, the connecting member 463, and the first conductive adhesive member 461. As the accumulated charges move to the ground portion 421 having a relatively low potential, accumulation of charges may not occur. Since the accumulated charges move to the ground portion 421, the charges may not be discharged to electronic components, and damage to the electronic components may be prevented.

In the above description, the discharge path E of charges has been described as being formed via the camera housing 450, the conductive adhesive member 460, and the ground portion 421 of the printed circuit board 420. The camera housing 450 may be electrically connected to the ground portion 421 via various types of conductive members in addition to the conductive adhesive member 460.

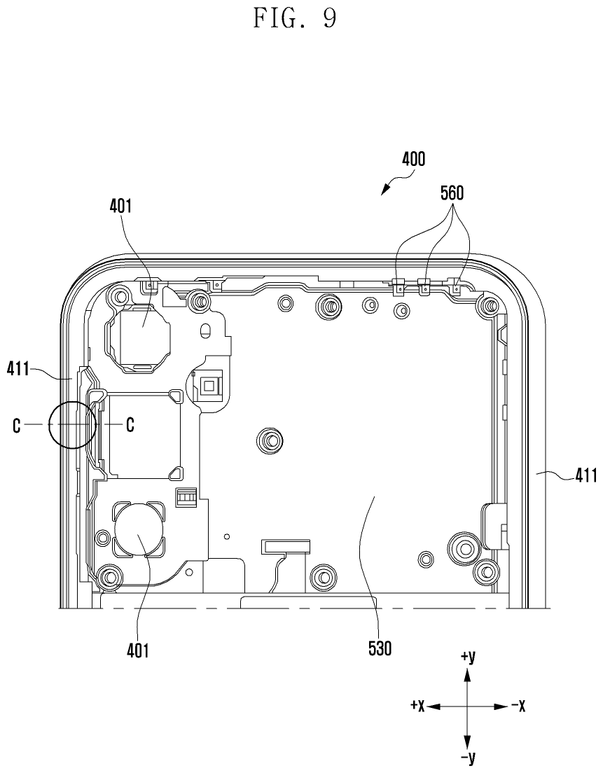

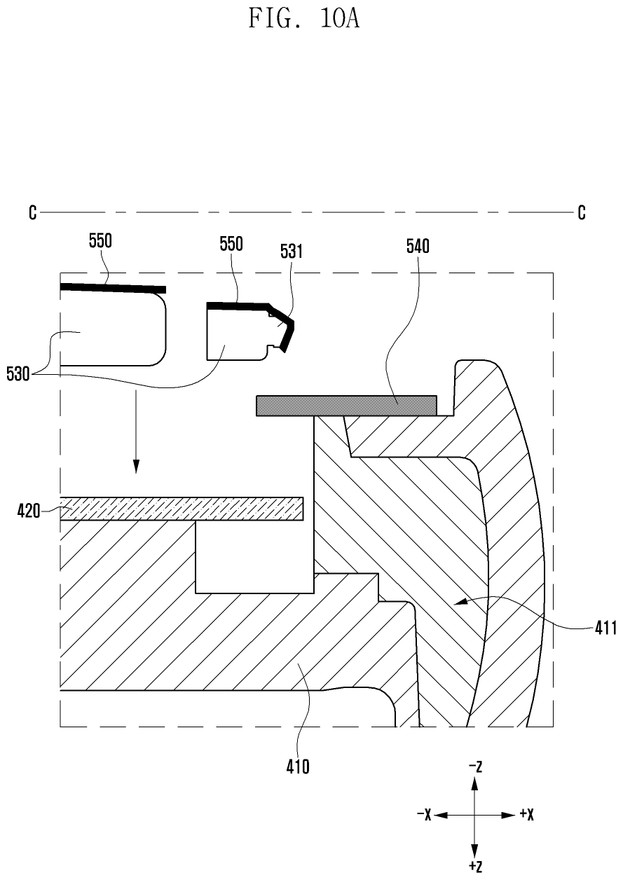

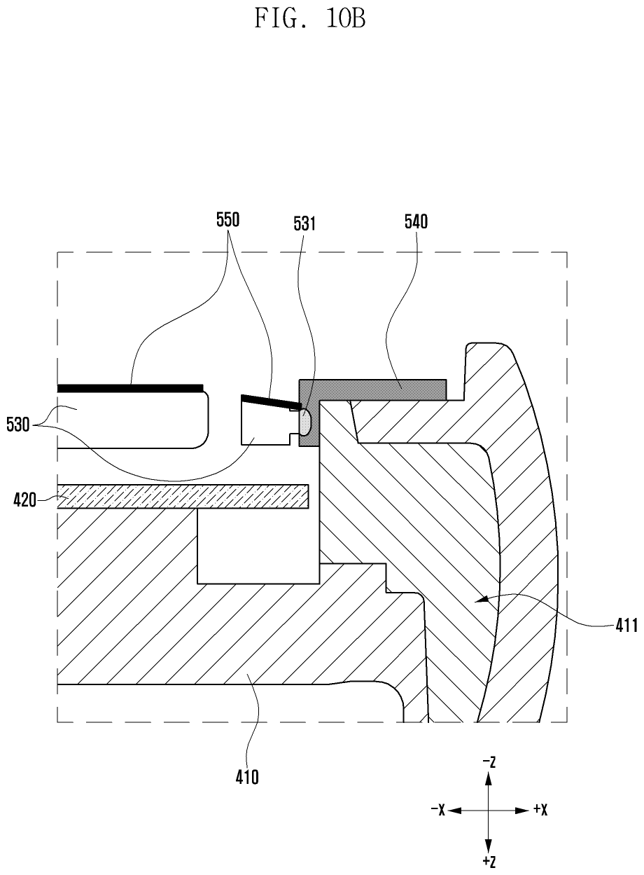

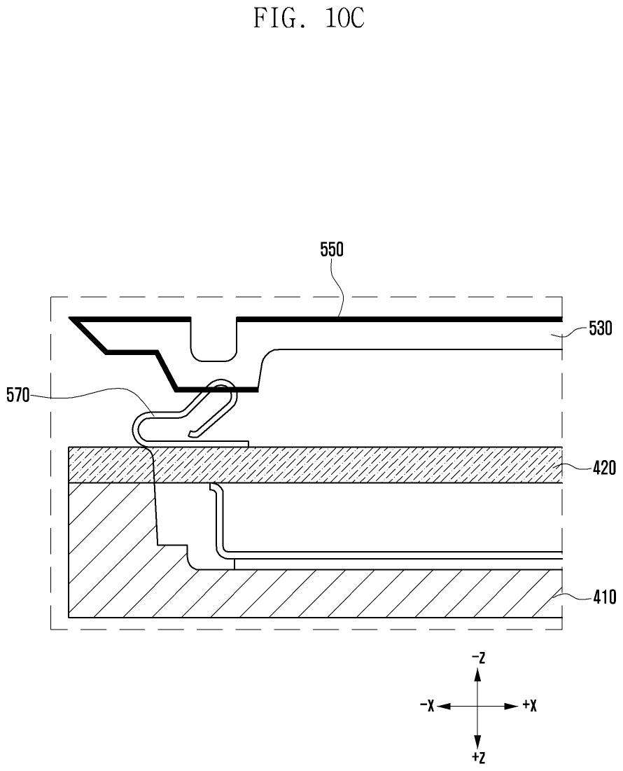

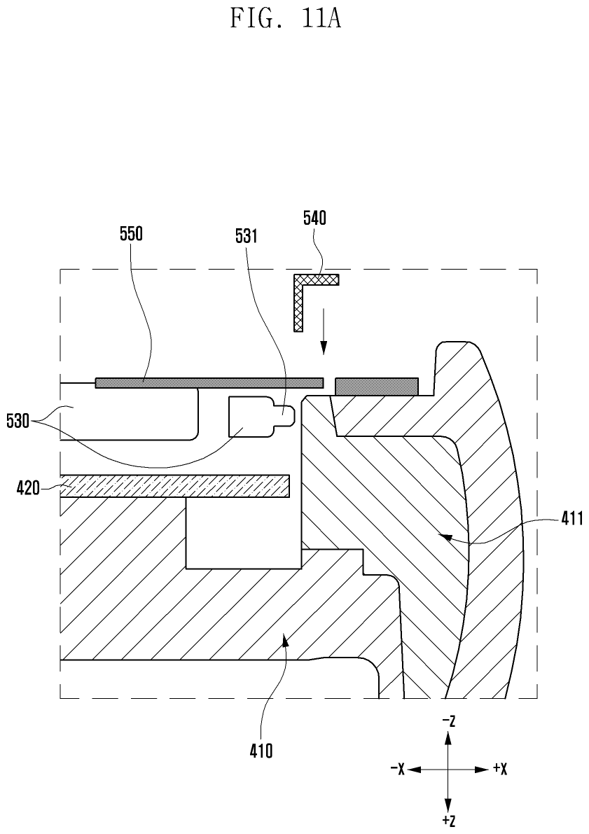

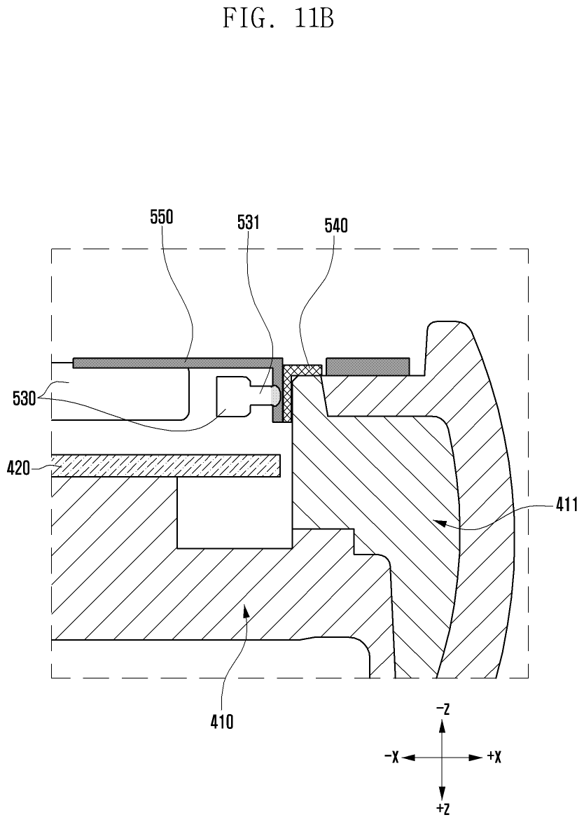

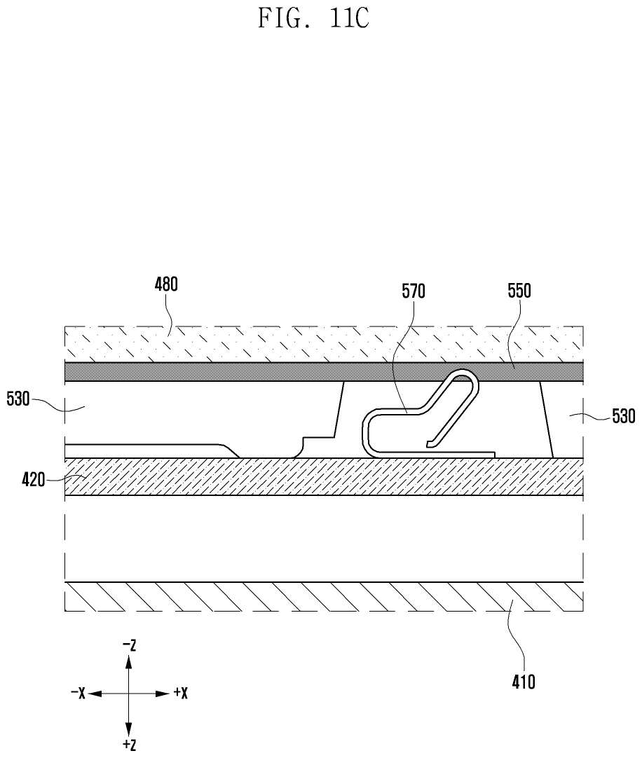

FIG. 9 is a view illustrating a state in which some components of the electronic device according to an embodiment of the disclosure are removed. FIGS. 10A to 10C are sectional views taken along line C-C of FIG. 9 and illustrate connection between a frame of the electronic device and a communication module disposed on a printed circuit board. FIGS. 11A to 11C are views illustrating connection between a frame of the electronic device and a communication module disposed on a printed circuit board in an embodiment different from that illustrated in FIGS. 10A to 10C.

According to an embodiment, as illustrated in FIG. 9, an electronic device 400 (e.g., the electronic device 101 of FIG. 1, the electronic device 200 of FIG. 2A or FIG. 2B, or the electronic device 300 of FIG. 3) may include a frame 411 (e.g., the side surface bezel structure 218 of FIG. 2A or the side surface member 310 of FIG. 3). The frame 411 may be disposed on the side surface of the housing 410 (e.g., the housing 210 of FIG. 2A) to form a side surface exterior of the electronic device 300. For example, the side surface of the electronic device 300 may refer to the surface excluding the front surface (e.g., the surface oriented in the +z direction in FIG. 4) and the rear surface (e.g., the surface oriented in the-z direction in FIG. 4) of the electronic device 300.

According to an embodiment, the frame 411 may be made of a conductive material and used as an antenna of the electronic device 400. For example, the frame 411 may be made of a metal material including aluminum (Al). This is an example, and the frame 411 may be made of various metal materials. The frame 411 may be electrically connected to a communication module (e.g., the communication module 180 in FIG. 1) connected to a printed circuit board 420 (e.g., the board 340 in FIG. 3) of the electronic device 400 and may transmit or receive a communication signal (e.g., RF signal) to or from an external device. In an embodiment, the frame 411 may be electrically connected to the communication module 180 via an RF member 560. For example, the RF member 560 may electrically connect the communication module 180 to the frame 411. Here, the RF member 560 may be a component that transmits a radio frequency (RF) signal. The RF member 560 may transmit an RF signal processed by the communication module 180 of the electronic device 400 to the frame 411 serving as an antenna, or may transmit an RF received by the frame 411 to the communication module 180.

According to an embodiment, the frame 411 may be physically split by split portions (not illustrated). As an insulating member made of a material having low conductivity or low permittivity is disposed in the split portion, the frame may be electrically split. In an embodiment, when the frame 411 is used as an antenna of the electronic device 400, an antenna resonance frequency may be determined depending on the physical length of the frame 411. For example, as described above, the frame 411 may be segmented into multiple portions having different lengths. In this case, the segmented frames 411 may have different resonance frequencies. When the frames 411 having different resonance frequencies are used, communications in various frequency bands (e.g., short-range communication and long-range communication) may be possible.

According to an embodiment, the printed circuit board 420 may have an edge adjacent to the frame 411. The RF member 560 may be disposed along the edge of the printed circuit board 420 and may be in contact with the frame 411. Meanwhile, depending on the shape of the printed circuit board 420, a portion of the frame 411 may be spaced apart from the edge of the printed circuit board 420. In such a case, the frame 411 may not be in contact with the RF member 560 disposed on the printed circuit board 420. In such a case, a portion of the frame 411 that is adjacent to the edge of the printed circuit board 420 may be in contact with the RF member 560. Accordingly, the portion of the frame that is adjacent to the printed circuit board 420 may be used as a side surface antenna.

According to an embodiment of the disclosure, a structure may be provided to electrically connect a portion of the frame 411, which is positioned apart from the printed circuit board 420, to the printed circuit board 420. Accordingly, the portion of the frame 411 that is spaced apart from the printed circuit board 420 may be used as an antenna. A detailed description of the structure connecting the frame 411 and the printed circuit board 420 will be provided below.

According to an embodiment, as illustrated in FIG. 10A, a first conductive member 540 may be disposed on the frame 411. The first conductive member 540 may be in contact with a second conductive member 550 disposed on a rear plate 530 (e.g., the rear plate 430 of FIG. 4A). In an embodiment, the rear plate 530 may include a protrusion 531 protruding toward the frame 411 from one surface. The second conductive member 550 may be disposed on the protrusion 531 of the rear plate 530 and one surface of the rear plate 530. In an embodiment, as illustrated in FIG. 10B, the rear plate 530 may be disposed in the housing 410 such that the second conductive member 550 comes into contact with the first conductive member 540 disposed on the frame 411. As the protrusion 531 of the rear plate 530 is inserted into the housing 410, the first conductive member 540 disposed on the frame 411 may be at least partially bent and positioned between the frame 411 and the protrusion 531. The protrusion 531 of the rear plate 530 may press the first conductive member 540 and the second conductive member 550. The first conductive member 540 and the second conductive member 550 may be compressed by the protrusion 531 and maintain contact. Meanwhile, referring to FIG. 10C, as the rear plate 530 is disposed in the housing 410, the second conductive member 550 may come into contact with a contact portion 570 connected to the communication module 180 on the printed circuit board 420. Accordingly, the frame 411 may be electrically connected to the contact portion 570 of the printed circuit board 420 via the first conductive member 540 and the second conductive member 550. Accordingly, the frame 411 may transmit an RF signal processed by the communication module 180 to the frame 411 serving as an antenna or may transmit an RF received by the frame 411 to the communication module 180.

According to an embodiment, as illustrated in FIGS. 11A and 11B, the first conductive member 540 may be inserted between the protrusion 531 of the rear plate 530 and the frame 411 in a state in which the rear plate 530 is seated in the housing 410. The first conductive member 540 may be inserted between the protrusion 531 of the rear plate 530 and the frame 411 to come into contact with the second conductive member 550 disposed on the rear plate 530. As the first conductive member 540 is inserted between the protrusion 531 and the frame 411, the second conductive member 550 may be bent. The protrusion 531 of the rear plate 530 may press the first conductive member 540 and the second conductive member 550. The first conductive member 540 and the second conductive member 550 may be compressed by the protrusion 531 and maintain contact. Meanwhile, referring to FIG. 11C, as the rear plate 530 is disposed in the housing 410, the second conductive member 550 may come into contact with a contact portion 570 connected to the communication module 180 on the printed circuit board 420. Accordingly, the frame 411 may be electrically connected to the contact portion 570 of the printed circuit board 420 via the first conductive member 540 and the second conductive member 550. Accordingly, the frame 411 may transmit an RF signal processed by the communication module 180 to the frame 411 serving as an antenna or may transmit an RF received by the frame 411 to the communication module 180.

In an embodiment, the first conductive member 540 and the second conductive member 550 may be made of various types of conductive materials. In an embodiment, the first conductive member 540 and the second conductive member 550 may be adhesive members made of a conductive material or metal plates. In some embodiments, the first conductive member 540 may be fabricated by plating a metal material on a portion of the frame 411 using a laser direct structuring (LDS) process. The second conductive member 550 may be fabricated by plating a metal material on a portion of the rear plate 530 using a laser direct structuring (LDS) process. The first conductive member 540 and the second conductive member 550 may be fabricated in various ways.

According to an embodiment of the disclosure, a portion of the frame 411 positioned apart from the printed circuit board 420 may be electrically connected to the printed circuit board 420. In an embodiment, as the first conductive member 540 in contact with the frame 411 comes into contact with the second conductive member 550 disposed on the rear plate 530, the frame 411 may be electrically connected to the communication module 180 of the printed circuit board 420. Accordingly, a portion of an area of the frame 411, which is spaced apart from an edge of the printed circuit board 420 so as not to come into contact with the RF member 560, may also be used as a side surface antenna.

In the above description, the frame 411 has been described as being in contact with the contact portion 570 of the printed circuit board 420 via the first conductive member 540 and the second conductive member 550, but the disclosure is not limited thereto. In an embodiment, the frame 411 may be electrically connected to the ground portion 421 of the printed circuit board 420 via the first conductive member 540 and the second conductive member 550 described above. For example, the second conductive member 550 disposed on the rear plate 530 may be in contact with the ground portion 421 of the printed circuit board 420. As the second conductive member 550 comes into contact with the first conductive member 540 disposed on the frame 411, an ESD discharge path E may be formed from the frame 411 to the ground portion 421.

According to an embodiment of the disclosure, an electronic device 400 (e.g., the electronic device 101 of FIG. 1, the electronic device 200 of FIG. 2A, or the electronic device 300 of FIG. 3) may include a printed circuit board 420 (e.g., the printed circuit board 340 of FIG. 3) including at least one ground portion 421, a camera module 401 (e.g., the camera module 180 of FIG. 1 or the camera module 212 of FIG. 2B) electrically connected to the printed circuit board, a camera bracket 440 disposed in a first direction (e.g., the −Z direction with reference to FIG. 4A) with respect to the camera module and including a first opening 443 corresponding to a lens of the camera module, a conductive adhesive member 460 disposed on the camera bracket and made of a conductive material to be connected to the ground portion of the printed circuit board, a camera housing 450 made of a metal material to form an exterior, e.g., a first exterior portion, of the electronic device and including a second opening 453 corresponding to the first opening and disposed in the first direction with respect to the camera bracket and in contact with the conductive adhesive member, and a cover member 480 forming an exterior, e.g., a second exterior portion, of the electronic device and including a third opening 483 positioned in the first direction with respect to the camera housing and configured to allow at least a portion of the camera housing to be exposed therethrough.

The camera bracket may include at least one first hole 444, the camera housing may include a first extension 451 inserted into the first hole of the camera bracket, and the conductive adhesive member may include a second extension 464 inserted into the first hole of the camera bracket and in contact with the first extension of the camera housing.

The camera bracket may include a body 441 and a seating portion 442 protruding from the body, and the conductive adhesive member may include a first conductive adhesive member 461 disposed on the body to bond the camera bracket and the cover member and including the second extension inserted into the first hole, and a second conductive adhesive member 462 disposed on the seating portion to bond the camera bracket and the camera housing.

The camera bracket may include a protrusion 447 protruding from a surface surrounding the first hole to press the first extension of the camera housing and the second extension of the conductive adhesive member.

The camera bracket may include a second hole 445 disposed adjacent to the first hole, and a partition wall 446 partitioning the first hole and the second hole. The protrusion is formed on the partition wall.

At least a portion of the second extension of the conductive adhesive member may be spaced apart from the camera bracket in the first direction.

The first extension of the camera housing may be inclined at a predetermined angle with respect to the first direction.

The camera housing may include a first groove 452-1 disposed on one side with respect to the first extension and a second groove 452-2 disposed on another side with respect to the first extension.

The camera bracket may include a body 441 and a seating portion 442 protruding from the body. The conductive adhesive member may include a first conductive adhesive member 461 disposed on the body to bond the camera bracket and a cover member, a second conductive adhesive member 462 disposed on the seating portion to bond the camera bracket and the camera housing, and a connecting member 463 connecting the first conductive adhesive member and the second conductive adhesive member.

The first conductive adhesive member, the second conductive adhesive member, and the connecting member of the conductive adhesive member may be integrated.

The camera housing may be formed in a ring shape.

The electronic device may further include a rear plate 530 on which the camera bracket is disposed, and a camera window 470 which is at least partially made of a transparent material and disposed on the camera housing to correspond to the second opening.

A camera structure is provided for protecting a camera module 401 (e.g., the camera module 180 of FIG. 1 or the camera module 212 of FIG. 2B) connected to a printed circuit board 420 (e.g., the printed circuit board 340 of FIG. 3) of an electronic device 400 (e.g., the electronic device 101 of FIG. 1, the electronic device 200 of FIG. 2A, or the electronic device 300 of FIG. 3) including at least one ground portion 421. The camera structure may include a camera bracket 440 disposed in a first direction (e.g., the −Z direction with reference to FIG. 4A) with respect to the camera module and including a first opening 443 corresponding to a lens of the camera module, a conductive adhesive member 460 disposed on the camera bracket and made of a conductive material to be connected to the ground portion of the printed circuit board, and a camera housing 450 made of a metal material to form an exterior of the electronic device. The camera housing may include a second opening 453 corresponding to the first opening and disposed in the first direction with respect to the camera bracket and in contact with the conductive adhesive member.

The bracket may include at least one first hole 444, the camera housing may include a first extension 451 inserted into the first hole of the camera bracket, and the conductive adhesive member may include a second extension 464 inserted into the first hole of the camera bracket and in contact with the first extension of the camera housing.

The camera bracket may include a body 441 and a seating portion 442 protruding from the body, and the conductive adhesive member may include a first conductive adhesive member 461 disposed on the body to bond the camera bracket and the cover member of the electronic device and including the second extension inserted into the first hole, and a second conductive adhesive member 462 disposed on the seating portion to bond the camera bracket and the camera housing.

The camera bracket may include a protrusion 447 protruding from a surface surrounding the first hole to press the first extension of the camera housing and the second extension of the conductive adhesive member.

The camera bracket may include a second hole 445 disposed adjacent to the first hole, and a partition wall 446 partitioning the first hole and the second hole. The protrusion is formed on the partition wall.

At least a portion of the second extension of the conductive adhesive member may be spaced apart from the camera bracket in the first direction.

The first extension of the camera housing may be inclined at a predetermined angle with respect to the first direction.

The camera bracket may include a body 441 and a seating portion 442 protruding from the body. The conductive adhesive member may include a first conductive adhesive member 461 disposed on the body to bond the camera bracket and a cover member of the electronic device, a second conductive adhesive member 462 disposed on the seating portion to bond the camera bracket and the camera housing, and a connecting member 463 connecting the first conductive adhesive member and the second conductive adhesive member.

What is claimed is:

1. An electronic device comprising:
a printed circuit board comprising at least one ground portion;
a camera connected to the printed circuit board;
a camera bracket positioned in a first direction with respect to the camera, wherein the camera bracket comprises a first opening corresponding to a lens of the camera;
a conductive adhesive member positioned on the camera bracket and connected to the at least one ground portion of the printed circuit board, the conductive adhesive member comprising a conductive material;
a camera housing forming a first exterior portion of the electronic device, wherein the camera housing comprises a metal material and a second opening corresponding to the first opening, and the camera housing is positioned in the first direction with respect to the camera bracket and contacts the conductive adhesive member; and
a cover member forming a second exterior portion of the electronic device and comprising a third opening positioned in the first direction with respect to the camera housing, wherein at least a portion of the camera housing is exposed through the third opening.

2. The electronic device of claim 1,
wherein the camera bracket further comprises at least one first hole,
wherein the camera housing further comprises a first extension positioned in the at least one first hole of the camera bracket, and
wherein the conductive adhesive member further comprises a second extension positioned in the at least one first hole of the camera bracket and contact the first extension of the camera housing.

3. The electronic device of claim 2,
wherein the camera bracket further comprises a body and a seating portion protruding from the body, and
wherein the conductive adhesive member further comprises:
a first conductive adhesive member positioned on the body, bonding the camera bracket to a cover member, the first conductive adhesive member comprising the second extension that is positioned in the at least one first hole, and
a second conductive adhesive member positioned on the seating portion, bonding the camera bracket to the camera housing.

4. The electronic device of claim 2, wherein the camera bracket further comprises a protrusion protruding from a surface surrounding the at least one first hole and pressing against the first extension of the camera housing and the second extension of the conductive adhesive member.

5. The electronic device of claim 4, wherein the camera bracket further comprises:
a second hole positioned adjacent to the at least one first hole; and
a partition wall partitioning the at least one first hole and the second hole, wherein the protrusion is positioned on the partition wall.

6. The electronic device of claim 2, wherein at least a portion of the second extension of the conductive adhesive member is separated from the camera bracket in the first direction.

7. The electronic device of claim 2, wherein the first extension of the camera housing is positioned at an angle with respect to the first direction.

8. The electronic device of claim 2, wherein the camera housing further comprises a first groove positioned on a first side with respect to the first extension and a second groove positioned on a second side with respect to the first extension.

9. The electronic device of claim 1,
wherein the camera bracket further comprises a body and a seating portion protruding from the body, and
wherein the conductive adhesive member further comprises:
a first conductive adhesive member positioned on the body, bonding the camera bracket to a cover member;
a second conductive adhesive member positioned on the seating portion, bonding the camera bracket to the camera housing; and
a connecting member connecting the first conductive adhesive member and the second conductive adhesive member.

10. The electronic device of claim 9, wherein the first conductive adhesive member, the second conductive adhesive member, and the connecting member are integrated.

11. The electronic device of claim 1, wherein the camera housing is formed in a ring shape.

12. The electronic device of claim 1, further comprising:
a rear plate on which the camera bracket is positioned; and
a camera window comprising a transparent material, wherein the camera window is positioned on the camera housing and corresponds to the second opening.

13. A camera structure for protecting a camera connected to a printed circuit board of an electronic device, the printed circuit board comprising at least one ground portion, the camera structure comprising:
a camera bracket positioned in a first direction with respect to the camera, wherein the camera bracket comprises a first opening corresponding to a lens of the camera;
a conductive adhesive member positioned on the camera bracket and connected to the at least one ground portion of the printed circuit board, the conductive adhesive member comprising a conductive material; and
a camera housing forming an exterior portion of the electronic device, wherein the camera housing comprises a metal material and a second opening corresponding to the first opening, and the camera housing is positioned in the first direction with respect to the camera bracket and contacts the conductive adhesive member.

14. The camera structure of claim 12, wherein the camera bracket further comprises at least one first hole,
wherein the camera housing further comprises a first extension positioned in the at least one first hole of the camera bracket, and
wherein the conductive adhesive member further comprises a second extension positioned in the at least one first hole of the camera bracket and in contact with the first extension of the camera housing.

15. The camera structure of claim 13, wherein the camera bracket further comprises a body and a seating portion protruding from the body, and
wherein the conductive adhesive member further comprises:
a first conductive adhesive member positioned on the body, bonding the camera bracket and a cover member of the electronic device, the first conductive adhesive member comprising the second extension positioned in the at least one first hole; and
a second conductive adhesive member positioned on the seating portion, bonding the camera bracket and the camera housing.

16. The camera structure of claim 13,
wherein the camera bracket further comprises:
a protrusion protruding from a surface surrounding the at least one first hole and pressing against the first extension of the camera housing and the second extension of the conductive adhesive member,

17. The camera structure of claim 13,
wherein the camera bracket further comprises:
a second hole positioned adjacent to the at least one first hole, and
a partition wall partitioning the at least one first hole and the second hole, the protrusion being positioned on the partition wall.

18. The electronic device of claim 14, wherein the second extension of the conductive adhesive member is a camera structure that is spaced apart from the camera bracket in the first direction.

19. The electronic device of claim 14, wherein the first extension of the camera housing is a camera structure that is tilted at a certain angle relative to the first direction.

20. The electronic device of claim 13, wherein the camera bracket comprises a body and a mounting portion protruding from the body, and the conductive adhesive member comprises:
a first conductive adhesive member disposed on the body, bonding the camera bracket and the cover member of the electronic device;
a second conductive adhesive member disposed on the mounting portion, bonding the camera bracket and the camera housing; and
a connecting member connecting the first conductive adhesive member and the second conductive adhesive member, forming the camera structure.
